(19) United States
(12) Patent Application Publication
(10) Pub. No.: US 2020/0118771 A1
(43) Pub. Date: Apr. 16, 2020

(54) Power Module of a Charging Station, Method for Equipping a Power Module and Charging Station with a Power Module

(71) Applicants: Hermann Obergünner, Remscheid (DE); Frank Schyma, Unna (DE); Kai Toekan, Dortmund (DE)

(72) Inventors: Hermann Obergünner, Remscheid (DE); Frank Schyma, Unna (DE); Kai Toekan, Dortmund (DE)

(73) Assignee: innogy SE, Essen (DE)

(21) Appl. No.: 16/654,210

(22) Filed: Oct. 16, 2019

(30) Foreign Application Priority Data
Oct. 16, 2018 (DE) 10 2018 125 599.3

(51) Int. Cl. H01H 9/02; H05K 1/18; H05K 3/30; H05K 3/34

(52) U.S. Cl. CPC H01H 9/0264; H05K 1/18; H05K 3/301; H05K 2201/10606; H01H 2207/02; H05K 2201/10053; H05K 3/3447

(57) ABSTRACT

Embodiments of a power module of a charging station are disclosed herein. The power module includes a printed circuit board, an electrical input for connection to an electrical supply network, an electrical output for connection to a charging control circuit, and a switching actuator electrically connected between the input and the output. The switching actuator is encapsulated in a housing and connected to the printed circuit board by connection contacts led out of the housing. According to the present disclosure, a base of a protective trough is arranged between the housing and the printed circuit board.

### CROSS-REFERENCE TO RELATED PATENT APPLICATIONS

This patent application claims the benefit of German Patent Application No. 10 2018 125 599.3, filed Oct. 16, 2018, the entire teachings and disclosure of which are incorporated herein by reference thereto.

### FIELD

Embodiments of the present disclosure are directed to a power module of a charging station, a method for equipping a power module and a charging station with such a power module.

### BACKGROUND

In current charging stations, electrical fuse elements, in particular mechanically switching elements such as relays and contactors, are usually dimensioned in such a way that they remain mechanically intact even in the event of tripping in the event of an overload. This means that the housing of these elements always remains intact, even if an overload occurs. In the case of overloads and switching under load, however, it regularly happens that the electrical function of the element is no longer given after switching despite the overdimensioning. Since the element is defective after the overload, it must be replaced anyway.

The switching elements used so far are heavy, large and expensive due to their oversizing. In addition, their assembly on printed circuit boards is problematic, since these cannot be soldered to the printed circuit boards, but must be attached manually. This makes the assembly process time-consuming. The only advantage of oversizing is that the elements can switch mechanically undamaged, i.e. without destroying the housing, in all operating situations.

The object was now based on the task of reducing the cost of equipping the power module, space consumption, as well as the weight and costs of a power module.

### BRIEF SUMMARY

This task is solved by a power module, a method and a charging station according to embodiments of the present disclosure.

In contrast to previous switching actuators, it is now proposed that the switching actuator is only designed for normal operation and can therefore be destroyed not only electrically but also mechanically in the event of an overload. However, this means that other elements of the printed circuit board can be affected both mechanically and electrically in the event of this mechanical destruction. In particular, if the housing of the switching actuator is destroyed, electrically conductive splinter parts are distributed over the entire circuit board so that it can no longer be used.

It is therefore proposed that the switching actuator be placed on the printed circuit board protected by a protective trough.

The circuit board in question, also called printed circuit board (PCB), is equipped with various discrete components and microcontrollers as well as microchips in order to enable an electrically safe connection of the charging station to an electrical supply network.

The circuit board in question has an electrical input for connection to an electrical supply network as well as an electrical output for connection to a charging control circuit. Both the input and the output can be provided as separate terminals to be connected to components that are physically separate from the power module. The power module can also be integrated with a charge control circuit on the same circuit board. The power module couples a charge control circuit to an electrical supply network.

One element of the power module is a switching actuator which is electrically connected between the input and the output on the printed circuit board. This switching actuator is a relay, contactor or other circuit breaker. This is encapsulated as a discrete component in its own housing. The switching actuator is connected to the printed circuit board via connection contacts led out of the housing.

The switch actuator in question is only designed for normal operation. In the event of an overload or a malfunction or switching under a load that is greater than intended, it will be explosively destroyed. Since there is then a risk that the housing will burst open and that splinter parts could destroy the power module beyond the switching actuator, it is suggested that a protective trough encapsulates the switching actuator. Here it is suggested that a bottom of a protective trough is first arranged between the housing and the printed circuit board.

In this case, the switching actuator is not placed directly on the printed circuit board, but a protective trough is provided between the housing of the switching actuator and the printed circuit board. This protective trough serves to shield the printed circuit board and the components arranged on the printed circuit board against splinter parts, which can be explosively distributed in the event of destruction of the switching actuator.

According to a design example, it is suggested that the bottom of the protective trough be provided with through-holes. The connection contacts are guided through these through-holes. The switching actuator with its housing is arranged on one side of the through-opening and on the other side of the through-opening only the connection contacts guided through the through-opening can be picked up.

The connection contacts guided through the through-opening are used for contacting the switching actuator with the printed circuit board. Contact areas can be provided on the printed circuit board for this purpose. In particular, the connection contacts can be pushed through the printed circuit board through connection holes and soldered to the printed circuit board on the side of the printed circuit board facing away from the switching actuator. It is also possible, however, that the connection contacts are mechanically inserted into receptacles which are mounted on the printed circuit board and held there in a force-locking and/or positive-locking manner.

According to a design example, it is suggested that the connection contacts are guided through the through-holes in a press fit. In particular, it is preferred that the connection contacts are larger in diameter between 0.1 mm and 0.2 mm than the clear width of the through-holes. The press fit ensures that the protective trough reliably seals the switching actuator against the printed circuit board. In particular, no splinters can pass through the through-holes.

According to a design example, it is suggested that the connection contacts are formed as solder tags. This makes it possible to solder the switching actuator directly to the printed circuit board via its connection contacts. The soldered connection simultaneously holds the protective trough between the housing of the switching contact and the printed circuit board.

According to a design example, it is suggested that the number of through holes exceeds the number of connecting contacts of a switching actuator, in particular it is twice as large as the number of connecting contacts of the switching actuator. For power modules there are different assembly variants in which one, two or more switching actuators have to be assembled. In Europe, for example, it is necessary to switch three phases and the neutral conductor, so that a total of four cable harnesses can be switched with switching actuators. In the USA, in a so-called single-phase three-wire network (also known as split-phase network), only two phases have to be switched, so that a total of two lines have to be switched with switching actuators.

In a switching actuator, two line paths can be switched preferentially. By using a switching actuator and four through-holes, one phase and one neutral can be switched. A further switching actuator with four connections and four further through-holes can be used to switch two further phases, so that one or two switching actuators can be used to equip variants for Europe and the USA. The protective trough should be used as flexibly as possible, so that it is provided with an excess of through-openings, so that depending on the component variant either one or two switching actuators or also several switching actuators are connected to the printed circuit board and can be protected by the protective trough.

According to a design example, it is suggested that a projection pointing inwards is provided in the floor. This projection can divide the floor into two areas. A switching actuator can be arranged in each area. The projection defines a positioning of the switching actuator on the floor of the protective tub. This simplifies the equipping of the power module with switching actuators.

According to a design example, it is suggested that the protective enclosure is formed by the floor and the side walls surrounding the floor. The side walls prevent splinters from being distributed on the printed circuit board.

Based on an example of the design, it is suggested that the protective trough be open on the side opposite the floor. It has been found that sufficient protection is already provided when the protective trough is formed without a cover. This has the advantage that a good heat dissipation at the switching actuators is possible and at the same time a sufficient splinter protection is given.

According to an example, it is suggested that the protective trough be made of a flame-retardant material, in particular a plastic. Since an explosion-like destruction of the switching actuator can occur in the event of an overload, especially with the formation of an arc, the protective trough should be sufficiently safe against flames. It is therefore also proposed that the material be class V0 according to UL94 “tests for flammability of plastic materials for parts in devices and appliances”, which is the US standard for flame-retardant materials. Accordingly, Class V0 is defined in DIN EN60695-11-10-20 and the CAN/CSAC22.2 standard.

According to a design example, it is suggested that the bottom and/or side walls have a wall thickness of less than 2 mm and more than 0.5 mm. This wall thickness has been found to be sufficiently stable with optimized material usage.

Another aspect is a procedure for loading a power module of a charging station. The circuit board, the switching actuator and the protective tray are provided. The switching actuator is encapsulated in a housing and has connection contacts that lead out of it. For mounting, the protective trough is positioned on the printed circuit board, the switching actuator with its connection contacts is guided through the through-holes of the protective trough and then the connection contacts are electrically contacted with the printed circuit board, in particular soldered. It is also possible that the protective trough is first equipped with the switching actuator, in which the connection contacts of the switching actuator are guided through the through-holes of the protective trough and the protective trough thus equipped is placed with the connection contacts on the printed circuit board, especially in contact areas, and soldered there.

Another aspect is a charging station with a power module as described herein.

### BRIEF DESCRIPTION OF THE DRAWINGS

In the following, the object is explained in more detail by means of a drawing showing examples of its design. In the drawings:

FIG. 1 a view of a protective trough;

FIG. 2 shows a top view of an unassembled printed circuit board; and

FIG. 3 a cross-section through an assembled printed circuit board.

### DETAILED DESCRIPTION

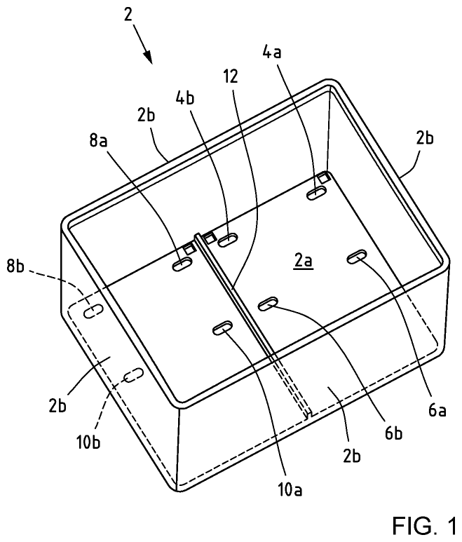

FIG. 1 shows a protective trough 2 with a base 2a and four side walls 2b enclosing the base. The bottom 2a of the protective trough 2 has several passage openings 4-10. A conductor path is connected in a switching actuator between two through-holes 4a, 4b, 6a, 6b; 8a, 8b and 10a, 10b each. The switching actuator with its connection contacts is inserted through the respective openings 4-6 and 8-10. The protective trough 2 can be equipped with two switching actuators and has a central web 12 which is arranged on the floor and points in the direction of the side walls. One switching actuator can be arranged on each side of the projection 12.

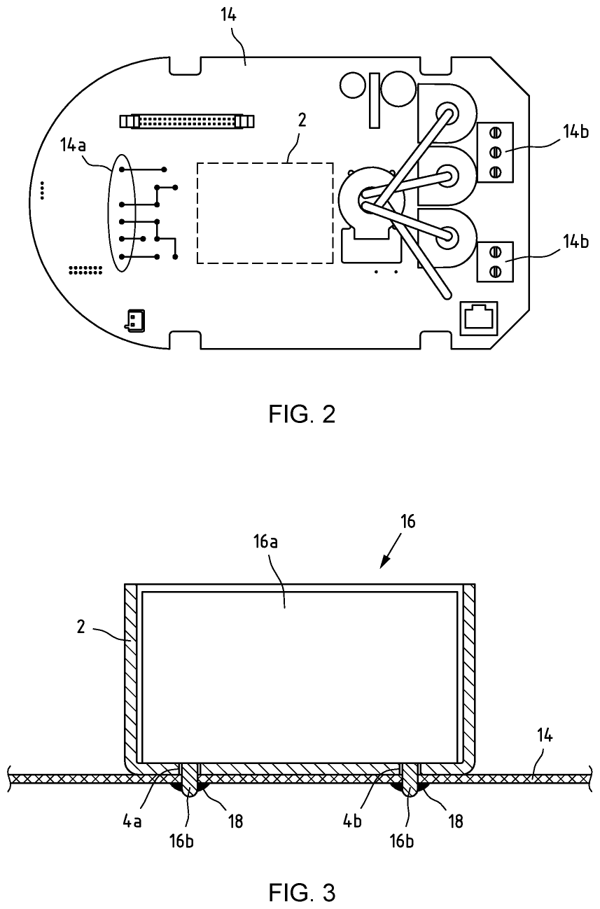

The protective trough 2 is fitted on a printed circuit board 14, as indicated in FIG. 2. The PCB 14 has an electrical input 14b and an electrical output 14a. The electrical input 14b can be formed by contact areas or terminal lugs and is used to connect a single-phase or three-phase electrical supply network. The electrical output 14a can also be formed by contact areas or terminal lugs and can also be prepared for a single-phase or three-phase connection of a charge controller.

Between input 14b and output 14a, protective circuits are provided at least for each phase and the neutral, including in particular a switching actuator. The switching actuator is used to switch one conductor path per phase or neutral between input 14b and output 14a.

For assembly, the circuit board 14 has a connection area on which the protective trough 2 can be placed. Contact areas, in particular solder points, are provided in the connection area for soldering the connection contacts of a switching actuator. When mounted, the holes of the connecting contacts on the printed circuit board 14 or the contact areas align with the through-holes 4-10 of the protective trough 2.

As shown in FIG. 3, the protective trough 2 is placed on the printed circuit board 14 for assembly. A switching actuator 16 with a housing 16a and connection contacts 16b is inserted into the protective tub 2 and inserted with the connection contacts 16b through two or four through-holes 4-6, 8-10. A conductor path can be switched through the switching actuator 16 between two connection contacts 16b. The switching actuator 16 is connected to the circuit board 14 with the aid of the connection contacts 16b. In particular, a solder connection 18 is formed between the connection contacts 16b and the contact areas of the printed circuit board 14 on the side of the printed circuit board 14 opposite the protective trough 2.

The protective trough 2 protects the printed circuit board 14 or the components installed on it from splinter parts which can occur if the switching actuator 16 switches at overload and is explosively destroyed. This is particularly the case if the switching actuator 16 is only designed for normal operating modes and is destroyed in the event of overload. The resulting arcs lead to an explosive destruction. The flying parts are stopped by the protective trough 2 so that they cannot come into contact with the rest of the circuit board 14.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A power module of a charging station, comprising:
a printed circuit board,
an electrical input for connection to an electrical supply network,
an electrical output for connection to a charging control circuit,
a switching actuator electrically switched between the input and the output, the switching actuator being encapsulated in a housing and being connected to the printed circuit board by means of terminal contacts guided out of the housing, and
a base of a protective trough arranged between the housing and the printed circuit board.

2. The power module according to claim 1, wherein the protective trough has through-openings in its base and wherein the connecting contacts are guided through the through-openings.

3. The power module according to claim 2, wherein the connection contacts are guided in press fit through the through-holes.

4. The power module according to claim 1, the connection contacts are formed as solder tabs.

5. The power module according to claim 1, wherein the number of through holes exceeds the number of connecting contacts of a switching actuator, in particular it is twice as large as the number of connecting contacts of the switching actuator.

6. The power module according to claim 1, wherein an inwardly pointing projection dividing the base into two regions is provided in the base, a switching actuator being arrangeable in each region.

7. The power module according to claim 1, wherein the protective trough is formed from the floor and side walls enclosing the floor.

8. The power module according to claim 1, wherein the protective trough is open on the side opposite the floor.

9. The power module according to claim 1, wherein the protective tub is made of a flame-retardant material, in particular a plastic, in particular a material of class V0, in accordance with UL94 “Tests for Flammability of Plastic Materials for Parts in Devices and Appliances”, IEC/DIN EN 60695-11-10 and -20 and/or Canadian CAN/CSA C 22.2.

10. The power module according to claim 1, wherein the base and/or the side walls have a wall thickness of less than 2 mm and more than 0.5 mm.

11. A method for equipping a power module of a charging station comprising,
providing a printed circuit board,
providing of a switching actuator with a housing and connection contacts led out of the housing,
providing of a protective trough,
wherein the protective trough is arranged between the housing and the printed circuit board,
wherein the connection contacts are guided through through-holes in the bottom of the protective trough, and
wherein the connecting contacts are electrically contacted with the printed circuit board, in particular are soldered.

12. A charging station comprising a power module according to claim 1.
